(19) United States
(12) Patent Application Publication
(10) Pub. No.: US 2016/0172617 A1
(43) Pub. Date: Jun. 16, 2016

(54) ORGANIC ELECTROLUMINESCENCE ELEMENT AND METHOD OF MANUFACTURING THE SAME

(71) Applicant: JOLED INC., Tokyo (JP)

(72) Inventors: Hideyuki SHIRAHASE, Tokyo (JP); Hiroyuki AJIKI, Tokyo (JP); Jun HASHIMOTO, Tokyo (JP)

(73) Assignee: JOLED INC., Tokyo (JP)

(21) Appl. No.: 14/963,628

(22) Filed: Dec. 9, 2015

(30) Foreign Application Priority Data
Dec. 12, 2014 (JP) 2014-251727

(51) Int. Cl. H01L 51/50; H01L 51/56; H01L 51/52

(52) U.S. Cl. CPC H01L 51/5096; H01L 51/5076; H01L 51/5265; H01L 51/56; H01L 51/5218; H01L 51/5234; H01L 51/5008; H01L 2251/558; H01L 2251/301; H01L 51/007

(57) ABSTRACT

An organic EL element includes: a light-reflective anode; a light-emitting layer that is disposed above the anode; a fluorine compound layer that is disposed on the light-emitting layer, and includes a fluorine compound including a first metal that is an alkali metal or an alkaline-earth metal; a functional layer that is disposed on the fluorine compound layer, and has at least one of an electron transport property and an electron injection property; a light-transmissive cathode that is disposed above the functional layer, and includes a metal layer, wherein the functional layer includes a second metal in a region thereof that is in contact with the fluorine compound layer, the second metal being an alkali metal or an alkaline-earth metal.

This application is based on an application No. 2014-251727 filed in Japan, the contents of which are hereby incorporated by reference.

### BACKGROUND OF THE DISCLOSURE

(1) Technical Field

The present disclosure relates to an organic electroluminescence (EL) and a method of manufacturing the organic EL element, and particularly to an organic EL element including a light-reflective anode and a light-transmissive cathode.

(2) Description of Related Art

In recent years, display devices employing an organic EL element have been becoming widespread owing to characteristics of the organic EL element such as a high visibility resulting from self-luminescence and an excellent shock resistance resulting from a fully solid-state structure thereof.

According to a structure of the organic EL element, at least a light-emitting layer is interposed between a pair of electrodes (an anode and a cathode). Further, the organic EL element mostly includes a functional layer (an electron transport layer, an electron injection layer, and so on) for supplying electrons to the light-emitting layer, a hole injection layer, a hole transport layer, and so on that are interposed between the light-emitting layer and the cathode.

There is a demand for improving light-extraction efficiency of the organic EL element from the standpoint of reducing power consumption, increasing the lifetime of the organic EL element, and so on. As an art of improving the light-extraction efficiency, there has been known an art of adopting an optical cavity to the organic EL element as disclosed for example in the application publication WO2012/020452 A1.

Also, it is known that an excellent electron injection property is exhibited by the functional layer made of an alkali metal or an alkaline-earth metal having a low work function.

On the other hand, an alkali metal and an alkaline-earth metal are easy to react with impurities such as moisture and oxygen. For this reason, impurities degrade the functional layer, which includes an alkali metal or an alkaline-earth metal. This might exercise an adverse effect such as degradation of luminous efficiency and reduction of light-emitting lifetime of the organic EL element. As a result, storage stability deteriorates.

In view of this problem, Japanese Patent No. 4882508 discloses an organic EL element including an inorganic barrier layer on a light-emitting layer in order to prevent degradation of a functional layer. Such an inorganic barrier layer ensures a property of blocking impurities, and prevents the functional layer from being degraded by impurities that are absorbed onto a surface of the light-emitting layer which is formed prior to the inorganic barrier layer.

### SUMMARY OF THE DISCLOSURE

According to the organic EL element disclosed in Japanese Patent No. 4882508, however, the inorganic barrier layer, which is provided on the light-emitting layer, is made of insulator, semiconductor, or metal having a work function of 4.0 eV or higher, and has a low electron injection property. Accordingly, sufficient electrons are not supplied from a cathode to the light-emitting layer, and as a result an excellent luminous property is sometimes not exhibited.

The present disclosure was made in view of the above problem, and aims to provide an organic EL element and a method of manufacturing the organic EL element according to which a sufficient property of blocking impurities, an excellent storage stability, and an excellent luminous property are exhibited.

In order to achieve the above aim, an organic EL element relating to one aspect of the present disclosure comprises: a light-reflective anode; a light-emitting layer that is disposed above the anode; a fluorine compound layer that is disposed on the light-emitting layer, and includes a fluorine compound including a first metal that is an alkali metal or an alkaline-earth metal; a functional layer that is disposed on the fluorine compound layer, and has at least one of an electron transport property and an electron injection property; a light-transmissive cathode that is disposed above the functional layer, and includes a metal layer, wherein the functional layer includes a second metal in a region thereof that is in contact with the fluorine compound layer, the second metal being an alkali metal or an alkaline-earth metal.

Here, the “first metal” indicates an element selected from an alkali metal or an alkaline-earth metal, and the “fluorine compound including the first metal” indicates a fluorine compound including the element selected from an alkali metal or an alkaline-earth metal. Also, the “second metal” indicates an element selected from an alkali metal or an alkaline-earth metal.

The “metal layer” may be made of a simple substance of a metal element such as Ag and Al, or may be made of an alloy of a plurality of metal elements.

According to the organic EL element relating to the above aspect, the fluorine compound layer includes the fluorine compound including the first metal which is an alkali metal or an alkaline-earth metal. The fluorine compound including the first metal has a high property of blocking impurities such as moisture and oxygen, and accordingly blocks intrusion of impurities from the light-emitting layer into the functional layer, and thereby prevents degradation of the functional layer and exhibits an excellent storage stability.

Also, the functional layer includes the second metal in the region thereof that is in contact with the fluorine compound layer. The second metal cleaves the bond between the first metal and fluorine in the fluorine compound including the first metal to liberate the first metal. The liberated first metal is an alkali metal or an alkaline-earth metal, and accordingly has a low work function and a high electron injection property. This exhibits an excellent electron supply property from the functional layer to the light-emitting layer, and thereby reduces driving voltage.

Further, according to the organic EL element relating to the above aspect, the cathode includes the metal layer. This improves light-extraction efficiency in an optical cavity of the organic EL element, and thereby reduces sheet resistance of the cathode.

### BRIEF DESCRIPTION OF THE DRAWINGS

These and other objects, advantages, and features of the technology pertaining to the present disclosure will become apparent from the following description thereof taken in conjunction with the accompanying drawings, which illustrate at least one specific embodiment of the technology pertaining to the present disclosure.

FIG. 1 is a cross-sectional view schematically showing a structure of an organic EL element relating to an embodiment.

FIG. 2 is a graph showing a relation between voltage and current density with respect to four specimens each including a second interlayer having a different thickness.

FIG. 3 is a graph showing luminous efficiency ratio that varies in accordance with variation of the thickness of the second interlayer.

FIG. 4A is a graph showing luminance retention that varies in accordance with variation of thickness of a first interlayer, FIG. 4B is a graph showing luminous efficiency ratio that varies in accordance with variation of the thickness of the first interlayer.

FIGS. 5A and 5B are graphs showing luminous efficiency ratio that varies in accordance with variation of ratio of the thickness of the second interlayer to the thickness of the first interlayer, with a different substance used for a hole transport layer.

FIG. 6 is a graph showing the luminous efficiency ratio that varies in accordance with variation of concentration of a metal with which an organic material included in the functional layer is doped.

FIGS. 7A and 7B explain optical interference that occurs in an optical cavity formed in the organic EL element with respect to Embodiments 1 and 2, respectively.

FIG. 8 is a graph showing results of an index luminance/y of blue light extracted from a blue organic EL element that was calculated through simulation performed by varying optical thickness of the functional layer.

FIG. 9 is a graph showing the index luminance/y of blue light extracted from the blue organic EL element that was calculated through simulation while varying the total thickness of a light-emitting layer, a first interlayer, and the functional layer from 5 nm to 200 nm.

FIGS. 10A-10C are partial cross-sectional views schematically showing a manufacturing process of the organic EL element relating to the embodiment, where FIG. 10A shows a state in which a TFT layer and an interlayer insulating layer are formed on a base material, FIG. 10B shows a state in which a pixel electrode is formed on the interlayer insulating layer, and FIG. 10C shows a state in which a barrier rib material layer is formed on the interlayer insulating layer and the pixel electrode.

FIGS. 11A-11C are partial cross-sectional views schematically showing the manufacturing process of the organic EL element relating to the embodiment, continuing from FIG. 10C, where FIG. 11A shows a state in which a barrier rib layer is formed, FIG. 11B shows a state in which a hole injection layer is formed on the pixel electrode within an opening of the barrier rib layer, and FIG. 11C shows a state in which a hole transport layer is formed on the hole injection layer within the opening of the barrier rib layer.

FIGS. 12A-12C are partial cross-sectional views schematically showing the manufacturing process of the organic EL element relating to the embodiment, continuing from FIG. 11C, where FIG. 12A shows a state in which a light-emitting layer is formed on the hole transport layer within the opening of the barrier rib layer, FIG. 12B shows a state in which a first interlayer is formed on the light-emitting layer and the barrier rib layer, and FIG. 12C shows a state in which a second interlayer is formed on the first interlayer.

FIGS. 13A-13C are partial cross-sectional views schematically showing the manufacturing process of the organic EL element relating to the embodiment, continuing from FIG. 12C, where FIG. 13A shows a state in which the functional layer is formed on the second interlayer, FIG. 13B shows a state in which a counter electrode is formed on the functional layer, and FIG. 13C shows a state in which a sealing layer is formed on the counter electrode.

FIG. 14 is a flow chart schematically showing the manufacturing process of the organic EL element relating to the embodiment.

FIG. 15 is a block diagram showing a structure of an organic EL display device including the organic EL element relating to the embodiment.

### DESCRIPTION OF EMBODIMENT

### Process by which the Present Disclosure was Achieved

As described above, it is possible to exhibit an excellent electron injection property from the functional layer to the light-emitting layer by forming the functional layer, which includes an element selected from an alkali metal and an alkaline-earth metal, on the light-emitting layer. On the other hand, the functional layer degrades due to intrusion of impurities such as moisture and oxygen from the light-emitting layer into the functional layer. Therefore, there is a demand for a method of preventing degradation of the functional layer while ensuring the electron injection property of the functional layer.

Here, fluoride of the first metal such as NaF and LiF has a low hygroscopicity and a high property of blocking impurities such as moisture and oxygen. The inventors found that degradation of the functional layer due to impurities is prevented by interposing a layer that is made of the fluoride of the first metal between the light-emitting layer and the functional layer. Also, the inventors found that an electron injection property from the functional layer to the light-emitting layer degrades due to disposition of a layer that is made of fluoride of the first metal between the light-emitting layer and the functional layer.

In view of these findings, the present inventors conceived of the present disclosure, specifically, found that it is possible to ensure both the property of blocking impurities by the interlayer and the electron supply property from the functional layer to the light-emitting layer by providing a layer that includes a second metal having a property of cleaving a bond between fluorine and an alkali metal or an alkaline-earth metal to liberate the first metal.

### Aspects of the Disclosure

An organic EL element relating to one aspect of the present disclosure comprises: a light-reflective anode; a light-emitting layer that is disposed above the anode; a fluorine compound layer that is disposed on the light-emitting layer, and includes a fluorine compound including a first metal that is an alkali metal or an alkaline-earth metal; a functional layer that is disposed on the fluorine compound layer, and has at least one of an electron transport property and an electron injection property; a light-transmissive cathode that is disposed above the functional layer, and includes a metal layer, wherein the functional layer includes a second metal in a region thereof that is in contact with the fluorine compound layer, the second metal being an alkali metal or an alkaline-earth metal.

The fluorine compound including the first metal, which is an alkali metal or an alkaline-earth metal, has a high property of blocking impurities. Accordingly, the first interlayer, which includes this fluorine compound, prevents intrusion of impurities from the light-emitting layer into the functional layer, and thereby prevents degradation of the functional layer and exhibits an excellent storage stability.

Also, the second metal, which is included in the functional layer, cleaves the bond between the first metal and fluorine in the fluorine compound including the first metal to liberate the first metal. The liberated first metal is an alkali metal or an alkaline-earth metal, and accordingly has a low work function and a high electron injection property. This exhibits an excellent electron supply property from the functional layer to the light-emitting layer, and thereby reduces driving voltage.

Also, according to the organic EL element relating to the above aspect, the cathode is made of a light-reflective metal material. This improves the light-extraction efficiency in an optical cavity formed between the anode and the cathode, and thereby reduces sheet resistance of the cathode.

A manufacturing method of an organic EL element relating to one aspect of the present disclosure comprises: forming a light-reflective anode: forming, above the anode, a light-emitting layer; forming, on the light-emitting layer, a fluorine compound layer that includes a fluorine compound including a first metal that is an alkali metal or an alkaline-earth metal; forming, on the fluorine compound layer, a functional layer that has at least one of an electron transport property and an electron injection property; forming, above the functional layer, a light-transmissive cathode that includes a metal layer, wherein the functional layer includes a second metal in a region thereof that is in contact with the fluorine compound layer, the second metal being an alkali metal or an alkaline-earth metal.

An organic EL element manufactured by this manufacturing method exhibits the same effect as that described above.

In the organic EL element and the manufacturing method relating to the above aspects, the following may be employed.

The metal layer may be made of silver, silver alloy, aluminum, or aluminum alloy. These metal materials have excellent reflectivity and conductivity, and accordingly are appropriate for improving the light-extraction efficiency in the optical cavity and reducing the sheet resistance of the cathode.

The second metal is an alkali metal or an alkaline-earth metal.

An alkali metal and an alkaline-earth metal have a comparatively low work function and a comparatively high electron supply property. Also, an alkali metal and an alkaline-earth metal have a comparatively high reactivity with fluorine. This facilitates to exhibit an effect of cleaving the bond between the first metal and fluorine to liberate the first metal.

The functional layer may be made of an organic material, the organic metal having an electron transport property and being doped with the second metal.

According to this, the functional layer has an electron transport property, and accordingly electrons are supplied effectively from the cathode to the light-emitting layer.

The functional layer may be doped with the second metal at a concentration of 5 wt % to 40 wt %. According to this, the functional layer has an excellent electron supply property, and accordingly an excellent luminous efficiency is exhibited.

The functional layer may include: an organic layer that is made of an organic material having an electron transport property; and an interlayer that is disposed between the organic layer and the fluorine compound layer, and is made of a simple substance of the second metal.

According to this, the functional layer includes the interlayer, which is made of the simple substance of the second metal, in the region thereof adjacent to the first interlayer. This improves the effect of cleaving the bond between the first metal and fluorine to liberate the first metal.

The second metal may be barium. Since barium is a versatile material, it is possible to achieve cost reduction by forming the functional layer and the interlayer from barium.

The first metal may be sodium. According to this, the first interlayer has an excellent property of blocking impurities because of including sodium fluoride having a low hygroscopicity and a low reactivity with oxygen. Also, since sodium has a low work function, an excellent electron injection property is exhibited from the first interlayer to the light-emitting layer.

In the case where the light-emitting layer emits blue light and an optical cavity is formed between the anode and the cathode, a total optical thickness of the light-emitting layer, the fluorine compound layer, and the functional layer may be set so as to correspond to an index luminance/y that falls within a range of the index luminance/y at a primary interference and is equal to or higher than a local maximum of the index luminance/y at a secondary interference and according to characteristics of the index luminance/y that varies in accordance with variation of an optical thickness of the functional layer, where luminance and y are luminance and a value y in an x-y chromaticity of the blue light extracted from the organic EL element, respectively.

According to this, blue light having a high luminance/y value is extracted from the organic EL element, it is possible to effectively extract blue light having an excellent color purity.

### Embodiment 1

The following explains an organic EL element relating to Embodiment 1 of the present disclosure. The following explanation is just an example for explaining a structure relating to one aspect of the present disclosure and effects thereof, and accordingly the present disclosure except the essence thereof is not limited to the embodiment explained below.

[I. Structure of Organic EL Element]

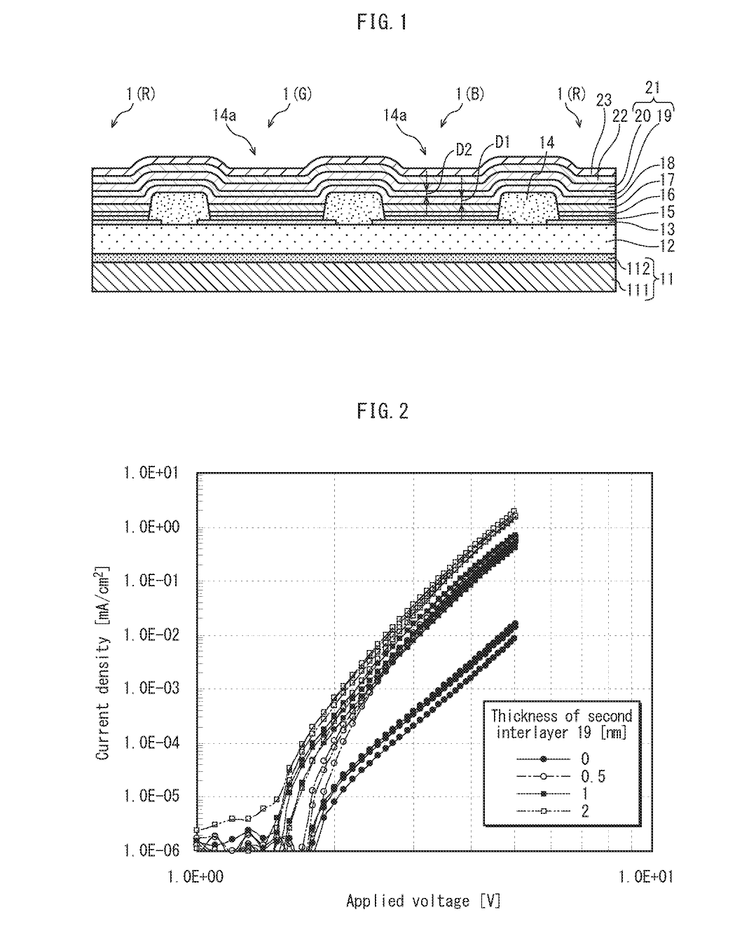

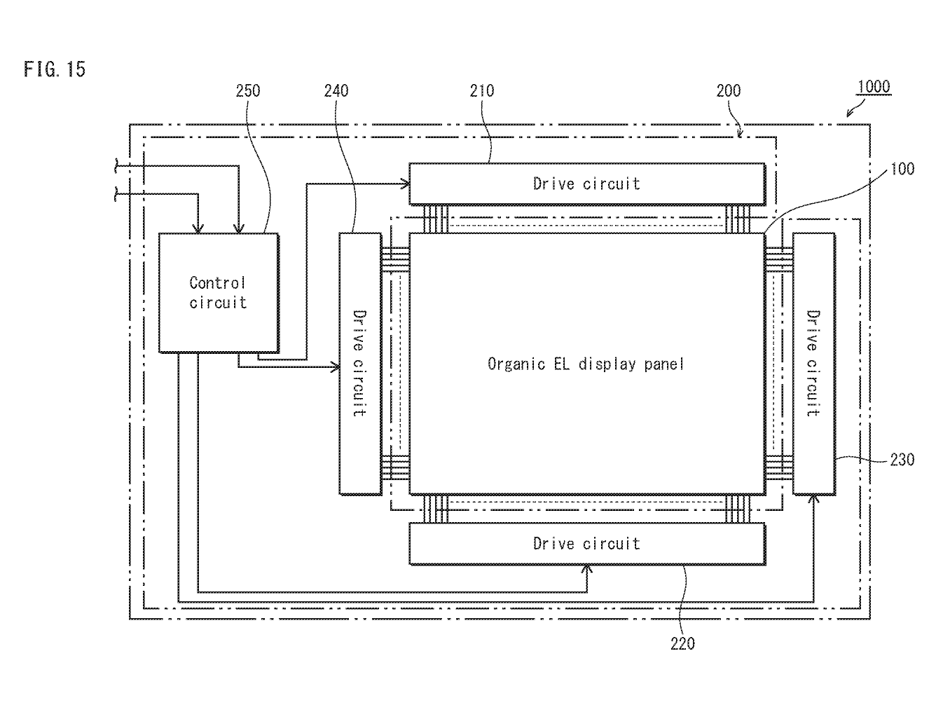

FIG. 1 is a partial cross-sectional view showing an organic EL display panel 100 relating to Embodiment 1 (see FIG. 15 see for the organic EL display panel 100). The organic EL display panel 100 includes a plurality of pixels each of which is composed of respective organic EL elements emitting light of three colors, namely organic EL elements 1(R), 1(G), and 1(B) emitting light of red, green, and blue colors, respectively. FIG. 1 shows the cross section of the blue organic EL element 1(B) and the periphery thereof.

In the organic EL display panel 100, the organic EL elements are of a so-called top-emission type according to which light is emitted forward (toward the upper side in FIG. 1).

The organic EL elements 1(R), 1(G), and 1(B) have substantially the same structure. Accordingly, these organic EL elements are hereinafter collectively explained as the organic EL elements 1.

As shown in FIG. 1, the organic EL elements 1 each include a substrate 11, an interlayer insulating layer 12, a pixel electrode 13, a barrier rib layer 14, a hole injection layer 15, a hole transport layer 16, a light-emitting layer 17, a first interlayer 18 (the fluorine compound layer in the present disclosure), a second interlayer 19 (the interlayer in the present disclosure), a functional layer 21, a counter electrode 22, and a sealing layer 23. Note that the substrate 11, the interlayer insulating layer 12, the first interlayer 18, the second interlayer 19, the functional layer 21, the counter electrode 22, and the sealing layer 23 are formed not for each of the organic EL elements 1, but for the entire organic EL elements 1 included in the organic EL display panel 100.

<Substrate>

The substrate 11 includes a base material 111 that is an insulating material and a thin film transistor (TFT) layer 112. The TFT layer 112 includes drive circuits formed therein each of the organic EL elements 1. The base material 111 is made for example of a glass material such as non-alkali glass, soda glass, non-fluorescent glass, phosphoric glass, boric gas, and quartz.

<Interlayer Insulating Layer>

The interlayer insulating layer 12 is formed on the substrate 11. The interlayer insulating layer 12 is provided in order to flatten unevenness on an upper surface of the TFT layer 112. The interlayer insulating layer 12 is made of a resin material such as a positive photosensitive material. Such a photosensitive material is acrylic resin, polyimide resin, siloxane resin, or phenol resin. Also, although not shown in the cross-sectional view in FIG. 1, the interlayer insulating layer 12 has a contact hole formed therein for each of the organic EL elements 1.

<Pixel Electrode>

The pixel electrode 13 includes a metal layer that is made of a light-reflective metal material. The pixel electrode 13 is formed on the interlayer insulating layer 12 for each of the organic EL elements 1, and is electrically connected with the TFT layer 112 via a corresponding contact hole.

In the present embodiment, the pixel electrode 13 functions as an anode.

Specific examples of the light-reflective metal material include silver (Ag), aluminum (Al), alloy of aluminum, molybdenum (Mo), alloy of silver, palladium, and copper (APC), alloy of silver, rubidium, and gold (ARA), alloy of molybdenum and chromium (MoCr), alloy of molybdenum and tungsten (MoW), and alloy of nickel and chromium (NiCr).

The pixel electrode 13 may be made of the metal layer alone, or have the multilayer structure including a layer made of metal oxide such as ITO and IZO that is layered on the metal layer.

<Barrier Rib Layer>

The barrier rib layer 14 is formed on the pixel electrode 13 so as to expose a partial region of an upper surface of the pixel electrode 13 and cover a peripheral region of the partial region. The partial region of the upper surface of the pixel electrode 13 that is not covered with the barrier rib layer 14 (hereinafter, referred to as an opening) corresponds to a subpixel. In other words, the barrier rib layer 14 has an opening 14a that is provided for each subpixel.

In the present embodiment, at a part where the pixel electrode 13 is not formed, the barrier rib layer 14 is formed on the interlayer insulating layer 12. In other words, at a part where the pixel electrode 13 is not formed, a bottom surface of the barrier rib layer 14 is in contact with an upper surface of the interlayer insulating layer 12.

The barrier rib layer 14 is made for example of an insulating organic material such as acrylic resin, polyimide resin, novolac resin, and phenol resin. In the case where the light-emitting layer 17 is formed using an applying method, the barrier rib layer 14 functions as a structure for preventing overflow of an applied ink. In the case where the light-emitting layer 17 is formed using a vapor deposition method, the barrier rib layer 14 functions as a structure for placing a vapor deposition mask. In the present embodiment, the barrier rib layer 14 is made of a resin material such as a positive photosensitive resin material. Such a photosensitive resin material is acrylic resin, polyimide resin, siloxane resin, or phenol resin. In the present embodiment, phenol resin is used.

<Hole Injection Layer>

The hole injection layer 15 is provided on the pixel electrode 13 within the opening 14a in order to promote injection of holes from the pixel electrode 13 to the light-emitting layer 17. The hole injection layer 15 is made for example of oxide such as silver (Ag), molybdenum (Mo), chromium (Cr), vanadium (V), tungsten (W), nickel (Ni), and iridium (Ir) or a conductive polymer material such as polyethylenedioxythiophene (PEDOT). In the case where the hole injection layer 15 is made of metal oxide, the hole injection layer 15 has a function of assisting generation of holes and stably injecting the holes to the light-emitting layer 17. The hole injection layer 15 has a high work function. In the present embodiment, the hole injection layer 15 is made of a conductive polymer material such as polyethylenedioxythiophene (PEDOT).

Here, in the case where the hole injection layer 15 is made of oxide of transition metal, the hole injection layer 15 has a plurality of energy levels because oxide of transition metal has a plurality of oxidation numbers. This facilitates hole injection, and therefore reduces driving voltage.

<Hole Transport Layer>

The hole transport layer 16 is formed within the opening 14a. The hole transport layer 16 is made of a high-molecular compound that does not have hydrophilic group. Such a high-molecular compound is for example, polyfluorene, polyfluorene derivative, polyallylamine, or polyallylamine derivative.

The hole transport layer 16 has a function of transporting holes, which are injected by the hole injection layer 15, to the light-emitting layer 17.

<Light-Emitting Layer>

The light-emitting layer 17 is formed within the opening 14a. The light-emitting layer 17 has a function of emitting light of R, G and B colors owing to recombination of holes and electrons. The light-emitting layer 17 is made of a known material. The known material is for example oxinoid compound, perylene compound, coumarin compound, azacouramin compound, oxazole compound, oxadiazole compound, perinone compound, pyrrolopyrrole compound, naphthalene compound, anthracene compound, fluorene compound, fluoranthene compound, tetracene compound, pyrene compound, coronene compound, quinolone compound and azaquinolone compound, pyrazoline derivative and pyrazolone derivative, rhodamine compound, chrysene compound, phenanthrene compound, cyclopentadiene compound, stilbene compound, diphenylquinone compound, styryl compound, butadiene compound, dicyanomethylenepyran compound, dicyanomethylenethiopyran compound, fluorescein compound, pyrylium compound, thiapyrylium compound, selenapyrylium compound, telluropyrylium compound, aromatic aldadiene compound, oligophenylene compound, thioxanthene compound, anthracene compound, cyanine compound, acridine compound, and metal complex of 8-hydroxyquinoline compound, metal complex of 2-2′-bipyridine compound, complex of a Schiff base and group III metal, oxine metal complex, fluorescent substance such as rare earth complex, or phosphor substance emitting phosphor light such as tris (2-phenylpyridine) iridium.

<First Interlayer>

The first interlayer 18 is formed on the light-emitting layer 17, and is made of fluoride of a first metal selected from alkali metal and alkaline-earth metal.

Alkali metal includes lithium, sodium, potassium, rubidium, cesium, or francium. Alkaline-earth metal includes calcium, strontium, barium, and radium. A film made of the fluoride has a function of blocking impurities.

Accordingly, the first interlayer 18 has a function of preventing impurities, which exist within or on respective surfaces of the light-emitting layer 17, the hole transport layer 16, the hole injection layer 15, and the barrier rib layer 14, from intruding into the functional layer 21 and the counter electrode 22.

The first metal should preferably be particularly Na or Li. The first interlayer 18 should preferably be made of sodium fluoride (NaF) or lithium fluoride (LiF).

<Functional Layer>

The functional layer 21 includes an organic material and a second metal. The organic material has a function of transporting electrons, which are injected from the counter electrode 22, to the light-emitting layer 17. The second metal is selected from alkali metal and alkaline-earth metal, and has a property of cleaving fluoride of the first metal (NaF).

The functional layer 21 includes a second interlayer 19 and an electron transport layer 20. The second interlayer 19 is formed directly on the first interlayer 18, and is made of a simple substance of the second metal. The electron transport layer 20 is formed on the second interlayer 19, and is made of an organic material having an electron transport property. The electron transport layer 20 is doped with the second metal.

The organic material of the electron transport layer 20 is for example a π-electron low molecular organic material such as oxadiazole derivative (OXD), triazole derivative (TAZ), and phenanthroline derivative (BCP, Bphen).

A metal is selected as the second metal from alkali metal (such as lithium, sodium, potassium, rubidium, and cesium) and alkaline-earth metal (such as magnesium, calcium, strontium, and barium) that has a property of cleaving the bond between the first metal and fluorine in the fluoride of the first metal included in the first interlayer 18.

In the present embodiment, barium (Ba) belonging to alkaline-earth metal is used as the second metal. Ba is an element that has a property of cleaving the bond between Na and F in NaF to liberate Na.

<Counter Electrode>

The counter electrode 22 is provided for the entire subpixels in common, and functions as a cathode.

The counter electrode 22 includes a metal layer that is made of a metal material. This metal layer has a thin thickness of approximate 10 nm to 30 nm, and accordingly is light-transmissive. Although a metal material is light-reflective, it is possible to ensure a light-transmissive property by reducing the thickness of the metal layer to 30 nm or lower.

Accordingly, part of light emitted from the light-emitting layer 17 is reflected off the counter electrode 22, and residue of the light transmits through the counter electrode 22.

In this way, inclusion of the metal layer in the counter electrode 22 reduces a sheet resistance of the counter electrode 22. The thickness of the metal layer of 10 nm or more reduces a surface resistance (Rs) thereof to 10 Ω/sq or less.

Also, inclusion of the metal layer in the counter electrode 22 improves a resonance effect of an optical cavity that is formed between the pixel electrode 13 and the counter electrode 22.

The metal material of the metal layer is silver (Ag), Ag alloy mainly containing Ag, aluminum (Al), or Al alloy mainly containing Al. Ag alloy is for example magnesium-silver alloy (MgAg) or indium-silver alloy. Ag has basically a low resistance. Ag alloy should preferably be used because of having an excellent heat resistance and a corrosion resistance and being capable of maintaining an excellent electrical conductivity for a long term.

Al alloy is for example magnesium-aluminum alloy (MgAl) or lithium-aluminum alloy (LiAl).

Other examples of alloy include lithium-magnesium alloy and lithium-indium alloy.

The metal layer may be made only of an Ag layer or an MgAg alloy layer. Alternatively, the metal layer may have a multilayer structure including the Mg layer and the Ag layer (Mg/Ag) or a multilayer structure including an MgAg alloy layer and the Ag layer (MgAg/Ag).

Further, the counter electrode 22 may be made only of the metal layer, or have a multilayer structure including a layer made of metal oxide such as ITO and IZO that is layered on the metal layer.

<Sealing Layer>

The sealing layer 23 is provided on the counter electrode 22 in order to suppress degradation of the light-emitting layer 17 due to exposure to moisture, oxygen, and so on. Since the organic EL display panel 100 is of the top-emission type, the sealing layer 23 is made of a light-transmissive material such as silicon nitride (SiN) and silicon oxynitride (SiON).

<Others>

Although not shown in FIG. 1, a color filter, an upper substrate, and so on may be adhered onto the sealing layer 23 via sealing resin. Adherence of the upper substrate protects the hole transport layer 16, the light-emitting layer 17, and the functional layer 21 against moisture, air, and so on.

[2. Property of Blocking Impurities and Electron Injection Property]

In the case where the hole injection layer 15, the hole transport layer 16, and the light-emitting layer 17 are formed by a wet process, when impurities, which exist within or on the respective surfaces of these layers, reach the functional layer 21, the impurities react with metal with which the organic material included in the functional layer 21 is doped, and thereby degrades the function of the functional layer 21.

Also, when the impurities react with the organic material, the organic material degrades and this might impair stability.

Also in the case where the barrier rib layer 14 is formed by the wet process, impurities, which exist within or on the surface of the barrier rib layer 14, similarly degrade the function of the functional layer 21.

In view of this, the organic EL element 1 relating to the present embodiment includes the first interlayer 18 and the second interlayer 19 between the light-emitting layer 17 and the functional layer 21, and the first interlayer 18 includes fluoride of an alkali metal or fluoride of an alkaline-earth metal.

Accordingly, this fluoride prevents intrusion of the impurities from the light-emitting layer 17.

Especially, NaF has an excellent property of blocking impurities because of having a low hygroscopicity and a low reactivity with oxygen, and accordingly prevents intrusion of the impurities from the light-emitting layer 17. This prevents reaction of alkali metal or alkaline-earth metal included in the functional layer 21 with impurities, and suppresses degradation of an electron supply property of the functional layer 21, and further prevents degradation of the counter electrode 22 due to impurities.

On the other hand, NaF has a high electron insulating property, and this causes a problem that NaF blocks movement of electrons, which are supplied from the counter electrode 22 and the functional layer 21, to the light-emitting layer 17, and as a result degrades luminous property. In view of this, in the organic EL element 1, the functional layer 21 includes the second interlayer 19, which is made of Ba as the second metal and is adjacent to the first interlayer 18. Ba has a function of cleaving the bond between Na and F in fluoride of Na (NaF), which is fluoride of the first metal included in the first interlayer 18. Accordingly, part of NaF in the first interlayer 18 dissociates and Na is liberated.

Na has a low work function and a high electron supply property, and accordingly assists movement of electrons from the functional layer 21 to the light-emitting layer 17. This suppresses degradation of the luminous property and reduces the driving voltage. Also, NaF in the first interlayer 18 exhibits a more excellent property of blocking impurities.

Note that the mechanism that cleaves the bond between the first metal and fluorine in the fluoride of the first metal is not limited to the above. Any mechanism may cleave the bond between the first metal and fluorine unless the mechanism impairs the functions of the light-emitting layer 17, the first interlayer 18, the second interlayer 19, the functional layer 21, and so on.

As described above, the first interlayer 18 includes the fluoride of the first metal, which has a high property of blocking impurities, and accordingly prevents intrusion of impurities from the light-emitting layer 17, and suppresses degradation of the electron supply property of the functional layer 21 (and the counter electrode 22). Also, the second interlayer 19 includes the second metal, which cleaves the bond between the first metal and fluorine. Accordingly, the first metal is liberated, and this facilitates electrons to move from the functional layer 21 to the light-emitting layer 17 through the first interlayer 18 which has a high insulating property. As a result, an excellent luminous property is exhibited.

Note that there is a case where the actual boundary between the first interlayer 18 and the second interlayer 19 is not clearly defined, and material of the first interlayer 18 and material of the second interlayer 19 are mixed together to a certain degree during the manufacturing process thereof. That is, the first interlayer 18 and the second interlayer 19 do not necessarily have precise thickness D1 and D2, respectively, and the boundary therebetween is unclear.

Even in this case, concentration of the first metal is higher in the light-emitting layer 17 than in the electron transport layer 20, and concentration of the second metal is higher in the electron transport layer 20 than in the light-emitting layer 17. Accordingly, the above effect is exhibited.

Here, in the case where the first interlayer 18 and the second interlayer 19 are formed by methods intended to form the first interlayer 18 and the second interlayer 19 having the thickness D1 and D2, respectively, the formed first interlayer 18 and second interlayer 19 are regarded as having the thickness D1 and D2, respectively, if not actually having the thickness D1 and D2. The same applies to the thickness of other layers.

[3. Test on Effects of Current Density Improvement by Second Interlayer]

Four specimens of the organic EL display panel 100 were created, and current density was measured by applying voltage to each of the specimens. The four specimens differ from each other in the thickness D2 of the second interlayer 19. Specifically, the respective four specimens include the second interlayer 19 having the thickness D2 of 0 nm, 0.5 nm, 1 nm, and 2 nm. The four specimens each include the first interlayer 18 having the thickness D1 of 4 nm.

FIG. 2 shows results of the measurement.

As shown in FIG. 2, compared with the specimen including the second interlayer 19 having the thickness D2 of 0 nm (that is, the specimen not including the second interlayer 19), a high current density was observed with respect to the respective specimens including the second interlayer 19 having the thickness D2 of 0.5 nm, 1 nm, and 2 nm. The results demonstrate that provision of the second interlayer 19 allows to supply a higher current to the light-emitting layer 17 included in the organic EL element 1.

Also, in comparison among the three specimens including the second interlayer 19 having the thickness D2 of 0.5 nm, 1 nm, and 2 nm, the highest current density was observed with respect to the specimen including the second interlayer 19 having thickness D2 of 2 nm. However, compared with a difference in current density between the respective two specimens including the second interlayer 19 having thickness D2 of 0 nm and 0.5 nm, a small difference exists in current density among the three specimens.

Therefore, a sufficient current density is achieved by including the second interlayer 19 having the thickness D2 of 0.5 nm or higher.

[4. Thickness of Second Interlayer and Luminous Efficiency Ratio]

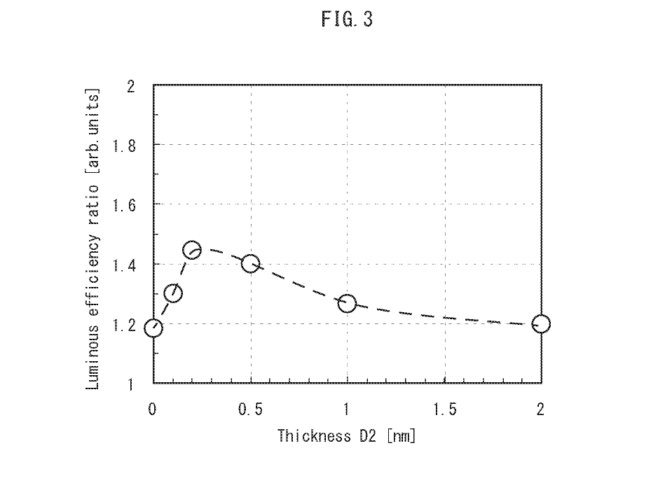

FIG. 3 is a graph showing luminous efficiency ratio with respect to six specimens of the organic EL display panel 100. The six specimens differ from each other in the thickness D2 of the second interlayer 19. The respective six specimens include the second interlayer 19 having the thickness D2 of 0 nm, 0.1 nm, 0.2 nm, 0.5 nm, 1 nm, and 2 nm. The six specimens each include the first interlayer 18 having the thickness D1 of 4 nm.

With respect to each of the six specimens, luminance was measured by applying voltage to the specimen such that current density is 10 mA/cm², and luminous efficiency was calculated from the measured luminance. Then, a ratio of the calculated luminous efficiency to a reference value for luminous efficiency of the organic EL display panel (luminous efficiency ratio) was plotted on the graph.

The reference value for luminous efficiency used here was a value of luminous efficiency of an organic EL display panel that does not include the second interlayer 19 and includes the hole transport layer 16 having a low hole injection property (specifically, tungsten oxide).

As shown in FIG. 3, the highest luminous efficiency ratio was observed with respect to the specimen including the second interlayer 19 having the thickness D2 of 0.2 nm. Also, substantially the same luminous efficiency ratio was observed with respect to the respective specimens including the second interlayer 19 having the thickness D2 of 2 nm and 0 nm. This is because of the following reason. A constant amount of holes are injected from the hole transport layer 16 to the light-emitting layer 17. Accordingly, even if an amount of electrons that is excessively high relative to the constant amount of holes is injected to the light-emitting layer 17 and thereby the current increases, the luminance does not increase. As a result, the luminous efficiency decreased, and the luminous efficiency ratio also decreased.

As shown in FIG. 3, since substantially the same luminous efficiency ratio was observed with respect to the respective specimens including the second interlayer 19 having the thickness D2 of 2 nm and 0 nm, the thickness D2 of the second interlayer 19 should preferably be 0.1 nm to 1 nm.

[5. Thickness of First Interlayer and Storage Stability]

A test of storage stability was performed with respect to three specimens of the organic EL display panel 100. The three specimens differ from each other in the thickness D1 of the first interlayer 18.

The respective three specimens include the first interlayer 18 having the thickness D1 of 1 nm, 4 nm, and 10 nm.

In the test of storage stability with respect to each of the specimens, initial luminance was measured by applying current to the specimen, the specimen was stored in an atmosphere of 80 degrees C. for seven days, and then luminance was measured again by applying current to the specimen. Then, luminance retention [%] (ratio of the luminance after storage at a high temperature to the initial luminance) was measured with respect to the specimen.

The storage stability was assessed using the luminance retention after storage at a high temperature.

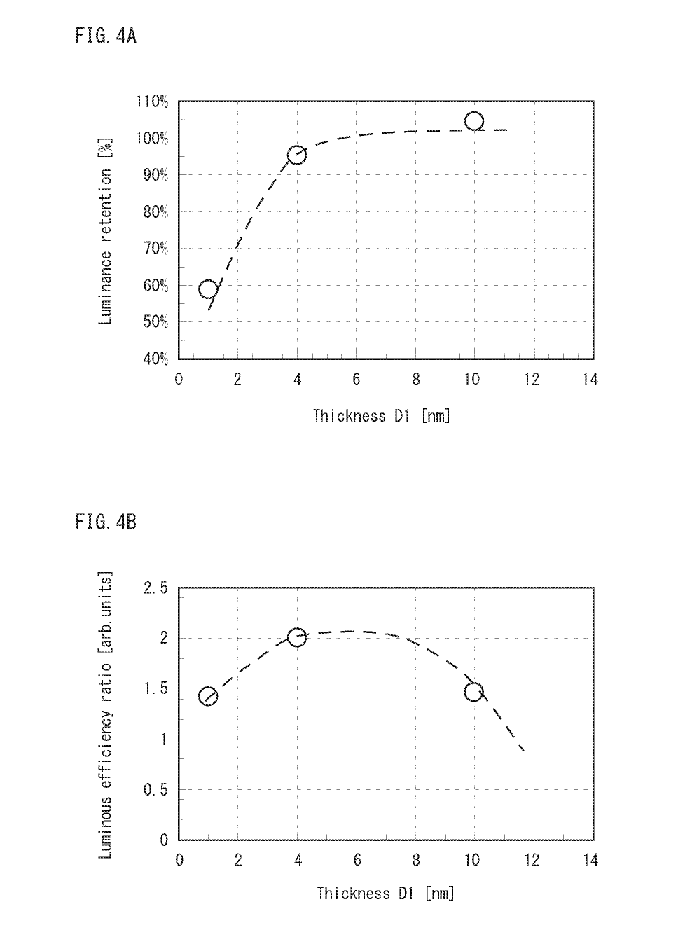

FIG. 4A is a graph showing results of the assessment.

As shown in FIG. 4A, with respect to the specimen including the first interlayer 18 having the thickness D1 of 1 nm, a luminance retention of 59% was observed and a low storage stability was exhibited. With respect to the specimen including the first interlayer 18 having the thickness D1 of 4 nm or more, a luminance retention of 95% or higher was observed and excellent storage stability was exhibited.

This demonstrates that it is possible to exhibit excellent storage stability, thereby prolonging the lifetime of the organic EL element, by including the first interlayer 18 having the thickness D1 of 4 nm or more.

Note that a luminance retention of more than 100% was observed with respect to the specimen including the first interlayer 18 having the thickness D1 of 10 nm. This is because it is considered that the balance between holes and electrons of the specimen, which has been in an inappropriate state before storage at a high temperature, became close to in an appropriate state owing to storage at the high temperature.

[6. Thickness of First Interlayer and Luminous Efficiency Ratio]

FIG. 4B is a graph showing luminous efficiency ratio with respect to three specimens of the organic EL display panel 100. The three specimens differ from each other in the thickness D1 of the first interlayer 18. The respective three specimens include the first interlayer 18 having the thickness D1 of 1 nm, 4 nm, and 10 nm. Similarly to the case of the luminous efficiency ratio shown in FIG. 3, luminance was measured by applying voltage to each of the three specimens such that current density is 10 mA/cm², and luminous efficiency was calculated from the measured luminance. Then, a ratio of the calculated luminous efficiency to a reference value for luminous efficiency of the organic EL display panel (luminous efficiency ratio) was plotted on the graph.

As shown in FIG. 4B, the highest luminous efficiency ratio was observed with respect to the specimen including the first interlayer 18 having the thickness D1 of 4 nm among the three specimens. Substantially the same luminous efficiency ratio was observed with respect to the respective specimens including the first interlayer 18 having thickness D1 of 1 nm and 10 nm.

From the above results, it is considered that when the thickness D1 of the first interlayer 18 is less than 1 nm and when the thickness D1 is more than 10 nm, a further low luminous efficiency ratio is observed. This is because of the following reasons. In the case where the thickness D1 of the first interlayer 18 is excessively small, an absolute amount of the first metal (Na in the present embodiment) reduces and this hinders promotion of movement of electrons from the functional layer 21 to the light-emitting layer 17. On the other hand, in the case where the thickness D1 of the first interlayer 18 is excessively large, the property of the first interlayer 18 as an insulating film increases. This degrades the luminous efficiency.

Therefore, the thickness D1 of the first interlayer 18 should preferably be 1 nm to 10 nm.

[7. Thickness Ratio of Second Interlayer to First Interlayer and Luminous Efficiency Ratio]

As described above, the first interlayer 18 needs to have the minimum thickness D1 for ensuring the property of blocking impurities. On the other hand, in the case where the thickness D1 is excessively large, the property of the first interlayer 18 as an insulating film increases. This interferes with injection of electrons to the light-emitting layer 17, and as a result sufficient luminance is not exhibited.

Also, in the case where the thickness D2 is excessively small, the second metal (Ba in the present embodiment), which is included in the second interlayer 19, cannot sufficiently liberate the first metal (Na in the present embodiment), which is included in the first interlayer 18. As a result, it is impossible to supply sufficient electrons to the light-emitting layer 17. On the other hand, in the case where the thickness D2 is excessively large, an amount of electrons, which is excessively high relative to an amount of holes supplied to the light-emitting layer 17, is supplied to the light-emitting layer 17. This degrades the luminous efficiency.

Further, in the case where the second interlayer 19 has the thickness D2 that is excessively large relative to the thickness D1 of the first interlayer 18, the second metal excessively liberates the first metal, and fluoride of the first metal reduces. As a result, the property of blocking impurities cannot be sufficiently exhibited by the first interlayer 18.

From the above results, the inventors supposed that a ratio of the thickness D2 to the thickness D1 (D2/D1) has a preferable range, as well as the first interlayer 18 and the second interlayer 19 each have a preferable thickness range. Then, the inventors checked how the luminous efficiency ratio varies by varying the ratio of the thickness D2 to the thickness D1 (D2/D1).

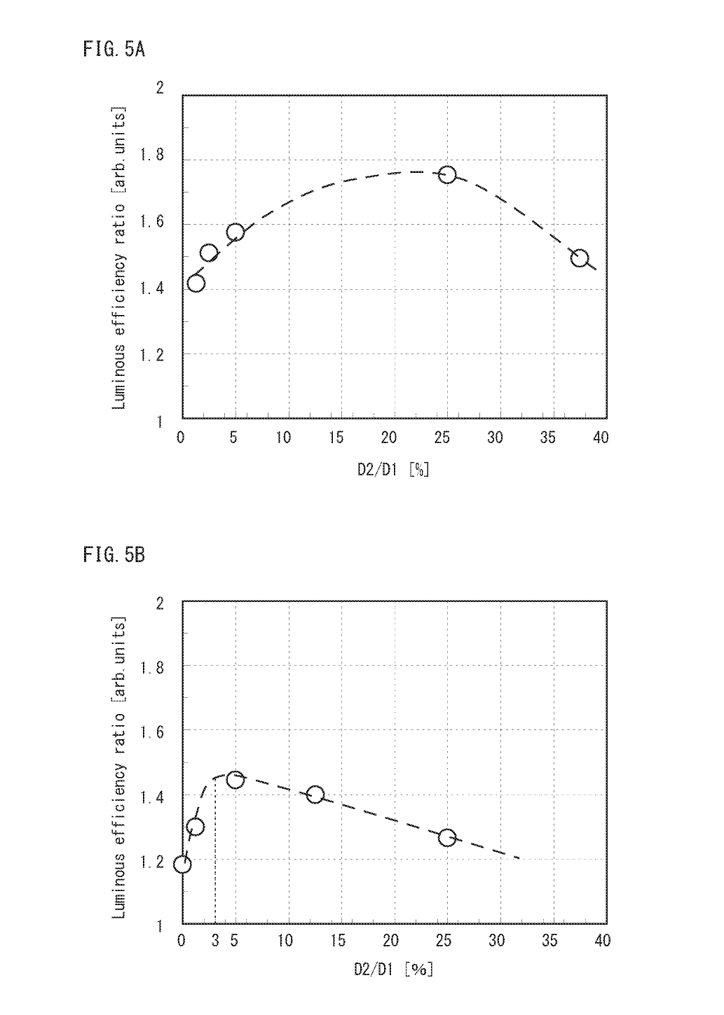

FIGS. 5A and 5B show results of variation of the luminous efficiency ratio.

Respective specimens shown in FIGS. 5A and 5B have basically the same structure except for the type of substance used for the hole transport layer 16. A hole transporting substance A used for the hole transport layer 16 shown in FIG. 5A has a higher hole supply property than a hole transporting substance B used for the hole transport layer 16 shown in FIG. 5B.

FIG. 5A is a graph in which the luminous efficiency ratio is plotted with respect to the respective five specimens that have the thickness ratio D2/D1 of 1.25%, 2.5%, 5%, 25%, and 37.5%. FIG. 5B is a graph in which the luminous efficiency is plotted with respect to the respective five specimens that have the thickness ratio D2/D1 of 0%, 1.25%, 5%, 12.5%, and 25%.

As shown in FIG. 5B, in the case where the hole transporting substance B, which has a comparatively low hole supply property, was used, a peak of the luminous efficiency ratio was observed when the thickness ratio D2/D1 was 3% to 5%. As shown in FIG. 5A, in the case where the hole transporting substance A, which has a comparatively high hole supply property, was used, a peak of the luminous efficiency ratio was observed when the thickness ratio D2/D1 was 20% to 25%.

The graphs in FIGS. 5A and 5B demonstrate that when the thickness ratio D2/D1 is 3% to 25%, a preferable luminous efficiency ratio is exhibited (that is, an excellent luminous efficiency is exhibited).

As described above, there is a case where the actual boundary between the first interlayer 18 and the second interlayer 19 is not clearly defined, and material of the first interlayer 18 and material of the second interlayer 19 are mixed together to a certain degree during the manufacturing process thereof. In such a case, excellent luminous efficiency is exhibited as long as a component ratio (mole ratio) of the second metal to the first metal is 1% to 10%.

[8. Concentration of Doping Metal in Electron Transport Layer and Luminous Efficiency Ratio]

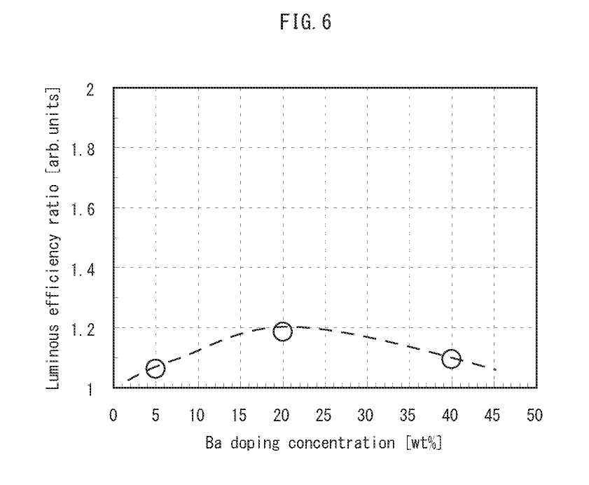

FIG. 6 is a graph showing luminous efficiency ratio that varies in accordance with variation of concentration of a doping metal included in the electron transport layer 20 with respect to three specimens. Here, the three specimens were each doped with barium (Ba). The respective three specimens have the concentration of the doping metal of 5 wt %, 20 wt %, and 40 wt %. The specimens each include the first interlayer 18 having the thickness D1 of 4 nm and the second interlayer 19 having the thickness D2 of 0.2 nm.

As shown in FIG. 6, the highest luminous efficiency ratio was observed with respect to the specimen including the electron transport layer 20 having the concentration of the doping metal of 20 wt % among the three specimens. Also, a luminous efficiency ratio of 1 or higher was observed with respect to each of the three specimens, and was more excellent than the reference value for luminous efficiency. This demonstrates that excellent luminous efficiency is exhibited when the functional layer 21 has the concentration of the doping metal of 5 wt % to 40 wt %.

When the electron transport layer 20 has the concentration of the doping metal (Ba) of 20 wt %, the maximum of the luminous efficiency was observed. Accordingly, the concentration of the doping metal should preferably be 20 wt % or lower (specifically, 5 wt % to 20 wt %) within the range of 5 wt % to 40 wt %.

In the present embodiment, since the second interlayer 19, which is made of a simple substance of Ba, is disposed on the first interlayer 18, an electron injection property is improved irrespective of a low concentration of the doping metal in the electron transport layer 20.

Therefore, it is possible to improve the electron injection property by the second interlayer 19 without including the second metal as the doping metal in the electron transport layer 20 (even with the concentration of the doping metal of 0 wt % in the electron transport layer 20).

[9. Optical Thickness of Layers and Optical Cavity]

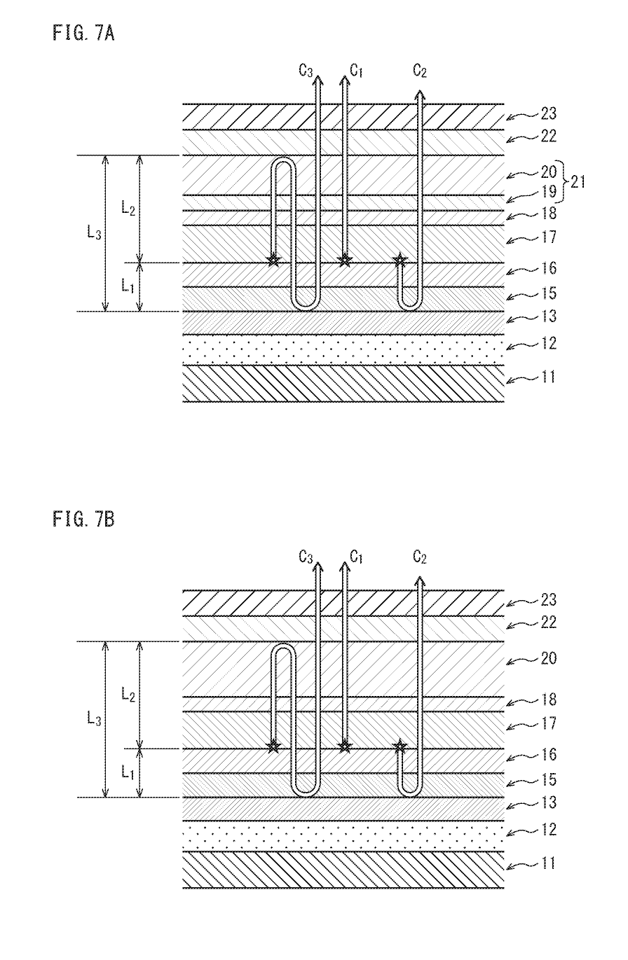

FIG. 7A explains optical interference that occurs in the optical cavity of the organic EL element relating to the present embodiment. The figure shows the organic EL element 1(B) including the light-emitting layer 17 emitting blue light, and explanation is provided here especially on the organic EL element 1(B).

In the optical cavity of the organic EL element 1(B), blue light is emitted from the vicinity of the interface of the light-emitting layer 17 with the hole transport layer 16, and transmits through the layers. Part of the light is reflected off the interface of each of the layers, and as a result optical interference occurs. The following exemplifies main types of optical interference.

(1) A first optical path C1 is formed in which part of light is emitted from the light-emitting layer 17 toward the counter electrode 22, transmits through the counter electrode 22, and is extracted to the outside of the organic EL element 1(B). A second optical path C2 is formed in which part of the light is emitted from the light-emitting layer 17 toward the pixel electrode 13, is reflected off the pixel electrode 13, then transmits through the light-emitting layer 17 and the counter electrode 22, and is extracted to the outside of the organic EL element 1(B). Then, interference occurs between direct light passing through the optical path C1 and reflected light passing through the optical path C2.

An optical thickness L1 shown in FIG. 7A corresponds to a difference in optical distance between the first optical path C1 and the second optical path C2. The optical thickness L1 is the total optical distance [nm] of the hole injection layer 15 and the hole transport layer 16, which are interposed between the light-emitting layer 17 and the pixel electrode 13 The optical distance of each of the layers is determined by a product of the film thickness by a refractive index.

(2) Further, a third optical path C3 is formed in which part of the light is emitted from the light-emitting layer 17 toward the counter electrode 22, is reflected off the counter electrode 22, is further reflected off the pixel electrode 13, and is extracted to the outside of the organic EL element 1(B).

Then, interference occurs between the light passing through the third optical path C3 and the light passing through the above first optical path C1.

An optical thickness L2 shown in FIG. 7A corresponds to a difference in optical distance between the second optical path C2 and the third optical path C3. The optical thickness L2 is the total optical distance of the light-emitting layer 17, the first interlayer 18, the second interlayer 19, and the functional layer 21.

Especially, in the organic EL element 1(B), since the counter electrode 22 includes the metal layer, light is easy to be reflected off the counter electrode 22 and therefore such interference tends to occur, compared with the case where the counter electrode 22 is made only of metal oxide.

(3) Moreover, interference occurs also between the light passing through the third optical path C3 and the light passing through the second optical path C2. An optical thickness L3 shown in FIG. 7A corresponds to a difference in optical distance between the first optical path C1 and the third optical path C3. The optical thickness L3 is the sum of the optical thickness L1 and L2 (L3=L1+L2).

Specifically, the optical thickness L3 is the total optical thickness of the hole injection layer 15, the hole transport layer 16, the light-emitting layer 17, the first interlayer 18, and the functional layer 21, which are interposed between the pixel electrode 13 and the counter electrode 22.

In the optical cavity, the optical thickness is generally adjusted so as to correspond to a local maximum of light-extraction efficiency. The optical thickness L1 between the light-emitting layer 17 and the pixel electrode 13, the optical thickness L2 between the light-emitting layer 17 and the counter electrode 22, and the optical thickness L3 between the pixel electrode 13 and the counter electrode 22 are set such that the light passing through the above optical paths reinforces each other by the interference, and thereby improves the light-extraction efficiency.

Such basic optical interference similarly occurs in the red organic EL element 1(R) and the green organic EL element 1(G).

According to the inventors' study, in the case where the blue organic EL element is set to have an optical thickness corresponding to a local maximum of the light-extraction efficiency, chromaticity of extracted blue light is not close to a target chromaticity. It is preferable to set the optical thickness so as to correspond to a range of the light-extraction efficiency that is shifted from the local maximum of the light-extraction efficiency such that blue light having a low value y in the chromaticity is extracted.

In other words, in the optical cavity formed in the blue organic EL element 1(B), when the optical thickness L1 between the light-emitting layer 17 and the pixel electrode 13 and the optical thickness L2 between the light-emitting layer 17 and the counter electrode 22 are varied, not only the light-extraction efficiency of blue light but also the chromaticity vary.

In view of this, the blue organic EL element 1(B) is adjusted so as to have an optical thickness corresponding to a high ratio of the luminance to the value y in an x-y chromaticity (index luminance/y), as explained in detail below.

Generally, a target chromaticity of blue light that is finally extracted from the blue organic EL element 1(B) is a value y of 0.08 or lower in the x-y chromaticity.

In the case where the value y in the x-y chromaticity of blue light extracted from the blue organic EL element 1(B) is far from the target chromaticity, it is necessary to correct the chromaticity to a large degree with use of a color filter. In this case, there is no choice but to use the color filter with a low light transmissivity. As a result, the light-extraction efficiency of the blue light extracted from the blue organic EL element 1(B), which is originally high, degrades to a large extent after the blue light passes through the color filter.

Therefore, in order to effectively extract blue light having the value y in the chromaticity of approximately 0.08 or lower, it is necessary to take into consideration not only increase of the light-extraction efficiency but also decrease of the value y in the chromaticity. In other words, it is necessary to set the optical thickness of each layer included in the blue organic EL element 1(B) by taking into consideration both the light-extraction efficiency and the value y in the chromaticity.

As a result of further study, the inventors found that, in order to effectively extract blue light having the value y in the chromaticity of approximately 0.08 or lower, the optical thickness of each of the layers should be set such that a high value of the index luminance/y is achieved, as disclosed in WO2012/020452 A1.

Based on this study, the index luminance/y is determined as an index with respect to the blue organic EL element 1(B), and the optical thickness L1 and L2 is set such that a high index is achieved. The following explains a specific example of the settings based on optical simulation.

(Optical Simulation)

With respect to the blue organic EL element 1(B) relating to an example in the present embodiment, the inventors performed simulation to calculate how the index luminance/y of blue light extracted from the blue organic EL element 1(B) varies in accordance with variation of each of the thickness of the hole transport layer 16 and the total thickness of the light-emitting layer 17, the first interlayer 18, and the functional layer 21.

This simulation is known as an optical simulation using a matrix method.

In the simulation, the organic EL element 1(B) having the structure shown in FIG. 7A was used, and the thickness of the hole transport layer 16 was varied from 5 nm to 200 nm.

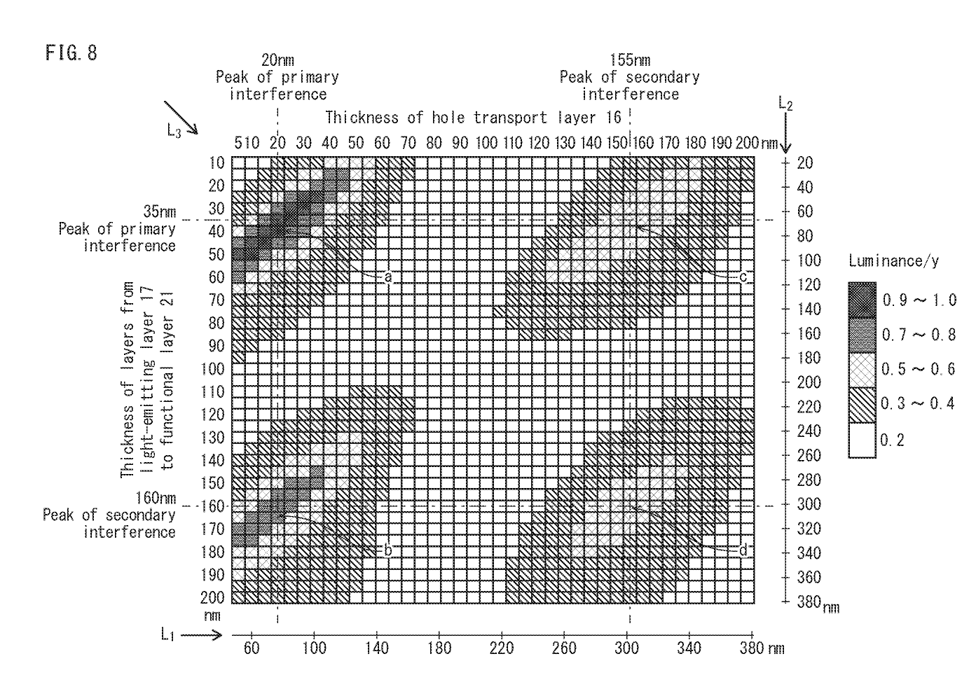

A graph in FIG. 8 has a horizontal axis representing the thickness of the hole transport layer 16 and a vertical axis representing the total thickness of the light-emitting layer 17, the first interlayer 18, and the functional layer 21. The thickness was varied at 5 nm intervals.

Here, the optical thickness L1 is the total optical thickness of the hole transport layer 16, the hole injection layer 15, and the metal oxide layer included in the pixel electrode 13. Accordingly, in the case where the thickness of the hole injection layer 15 and the metal oxide layer included in the pixel electrode 13 is fixed, the optical thickness L1 varies in accordance with variation of the thickness of the hole transport layer 16. The horizontal axis in FIG. 8 also represents the optical thickness L1.

Similarly, the optical thickness L2 is the total optical thickness of the light-emitting layer 17, the first interlayer 18, and the functional layer 21, and varies in accordance with variation of the total thickness of the light-emitting layer 17, the first interlayer 18, and the functional layer 21. The vertical axis in FIG. 8 also represents the optical thickness L2.

The optical thickness L3 is the sum of the optical thickness L1 and L2, and accordingly increases in a diagonal direction indicated by an arrow L3 in FIG. 8.

The highest value of the index luminance/y was determined as 1, and relative values of the index luminance/y were mapped to separate numerical ranges (0.2, 0.3-0.4, 0.5-0.6, 0.7-0.8, and 0.9-1.0) in the graph.

In the graph in FIG. 8, a peak (local maximum) of the index luminance/y clearly appears at each of four intersection points (a, b, c, and d) between respective dashed lines, which indicate 20 nm and 155 nm as the thickness of the hole transport layer 16 and extend in the vertical direction, and respective dashed lines, which indicate 35 nm and 160 nm as the total thickness of the light-emitting layer 17, the first interlayer 18, and the functional layer 21 and extend in the horizontal direction. That is, when the thickness of the hole transport layer 16 is 20 nm or 155 nm and the total thickness of the light-emitting layer 17, the first interlayer 18, and the functional layer 21 is 35 nm or 160 nm, a local maximum of the index luminance/y appears.

When the thickness of any of the layers included in the organic EL element 1(B) is varied, a local maximum of the index luminance/y of extracted blue light appears. In the present Description, appearance of such a local maximum is represented as an interference, and as the thickness increases, the order of the interference increases. For example, a local maximum of the index luminance/y appears at the smallest thickness is a primary interference, and a local maximum of the index luminance/y appears at the second smallest thickness is a secondary interference.

In a relation between the index luminance/y and the optical thickness L1 (the thickness of the hole transport layer 16), a peak of the primary interference appears at the points a and b, and a peak of the secondary interference appears at the points c and d. The index luminance/y is higher at the peak of the primary interference than at the peak of the secondary interference. In a relation between the index luminance/y and the optical thickness L2 (the total thickness of the light-emitting layer 17, the first interlayer 18, and the functional layer 21), the peak of the primary interference appears at the points a and c, and the peak of the secondary interference appears at the points b and d. The index luminance/y is higher at the peak of the primary interference than at the peak of the secondary interference.

Here, the peak of the primary interference corresponds to the smallest one among values of the optical thickness at which a local maximum of the index luminance/y appears, and the peak of the secondary interference corresponds to the second smallest one among the values of the optical thickness at which a local maximum of the index luminance/y appears.

The above simulation proves that it is possible to extract blue light having a higher index luminance/y from the organic EL element 1(B) not only by setting the optical thickness L1 so as to correspond to a peak of interference but also by setting the optical thickness L2 so as to correspond to a peak of interference.

The above simulation further proves that a high index luminance/y is obtained (high optical resonance effect is achieved) especially at the point a where both the peak of the primary interference relating to the optical thickness L1 and the peak of the primary interference relating to the optical thickness L2 appear.

Here, a high peak of the interference relating to the optical thickness L2 is considered to be caused by the metal layer included in the counter electrode 22. Accordingly, inclusion of the metal layer in the counter electrode 22 improves the optical resonance effect.

(Optical Thickness L2 and Index Luminance/y)

The following focuses on the optical thickness L2, and analyzes how the index luminance/y varies in accordance with variation of the optical thickness L2 while the optical thickness L1 is fixed to a constant value corresponding to the primary interference.

The optical thickness L1 corresponds to the primary interference when the thickness of the hole transport layer 16 is 20 nm, that is, when the optical thickness L1 is 76 nm, as shown in FIG. 8.

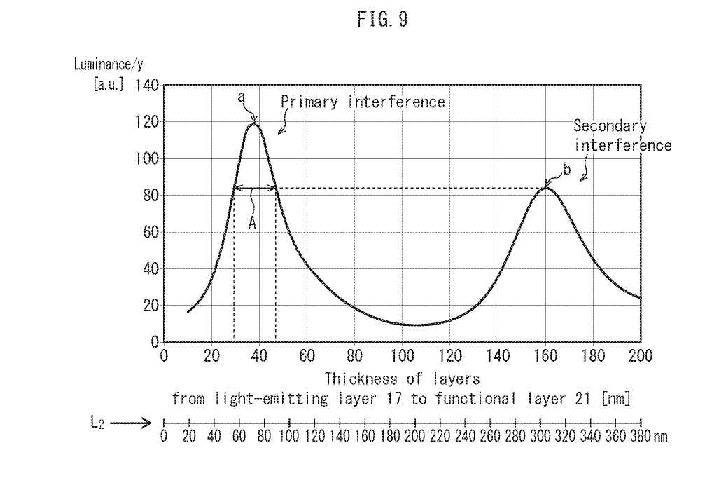

FIG. 9 is a graph showing results of simulation performed with respect to the index luminance/y of blue light extracted from the blue organic EL element 1(B) while varying the total thickness of the light-emitting layer 17, the first interlayer 18, and the functional layer 21 from 5 nm to 200 nm (varying the optical thickness L2 from 9.5 nm to 380 nm) when the optical thickness L1 corresponds to the primary interference.

The optical thickness L2 has a value that is the sum of respective products of the thickness of each of the light-emitting layer 17, the first interlayer 18, and the functional layer 21, which are represented in the horizontal axis, by the refractive index.

As shown in the graph in FIG. 9, the peak of the primary interference and the peak of the secondary interference appear in an ascending order of the optical thickness L1. In an optical simulation, the local maximum of the index luminance/y at the peak a of the primary interference is higher than the local maximum of the index luminance/y at the peak b of the secondary interference.

Therefore, the results of the optical simulation prove that the index luminance/y of blue light extracted from the organic EL element 1(B) is increased by setting the thickness of the functional layer 21 so as to correspond to the peak of the primary interference. This allows effective extraction of blue light having an excellent chromaticity.

Particularly, it is preferable to set the total thickness of the light-emitting layer 17, the first interlayer 18, and the functional layer 21 so as to fall within a range A shown in the graph in FIG. 9 in order to effectively extract blue light having an excellent chromaticity. The range A is included in a range of the total thickness of the light-emitting layer 17, the first interlayer 18, and the functional layer 21 at which the peak of the primary interference appears, and corresponds to the index luminance/y estimated from the actual efficiency that is higher than a local maximum of the index luminance/y estimated from the actual efficiency corresponding to the peak of the secondary interference.

The range A is a range of the total thickness of the light-emitting layer 17, the first interlayer 18, and the functional layer 21 from 29 nm to 44 nm, and a range of the optical thickness L2 of 29×1.9=55 nm to 44×1.9=84 nm.

Therefore, it is particularly preferable to set the optical thickness L1 to approximate 76 nm (for example, 60 nm to 90 nm), which corresponds to the primary interference, and set the optical thickness L2 to 55 nm to 84 nm in order to effectively extract blue light having an excellent chromaticity from the organic EL element 1(B).

FIG. 9 shows the results of the simulations with respect to when the optical thickness L1 corresponds to the peak of the primary interference (when the thickness of the hole transport layer 16 is 20 nm). Referring to FIG. 8, it is found that also when the optical thickness L1 corresponds to the peak of the secondary interference (also when the thickness of the hole transport layer 16 is 155 nm and the optical thickness L1 is 305.5 nm), a graph is obtained which shows an entirely low index luminance/y but has the similar shape as those in FIG. 9.

Therefore, it is also preferable to set the optical thickness L1 to approximate 305.5 nm (for example, 290 nm to 320 nm), which corresponds to the secondary interference, and set the optical thickness L2 to 55 nm to 84 nm in order to effectively extract blue light having an excellent chromaticity from the organic EL element 1(B).

In this way, it is preferable to set the optical thickness L1 to fall within a range appropriate for optical interference, and set the optical thickness L2 to 57 nm to 84 nm in order to effectively extract blue light having an excellent chromaticity from the organic EL element 1(B).

As explained above, with respect to the blue organic EL element 1(B), it is preferable to set the optical thickness L1 and L2 such that the index luminance/y increases. Also with respect to each of the organic EL element 1(R) and the organic EL element 1(B), it is preferable to similarly set the optical thickness L1 and L2 such that the luminance increases.

[10. Manufacturing Method of Organic EL Element]

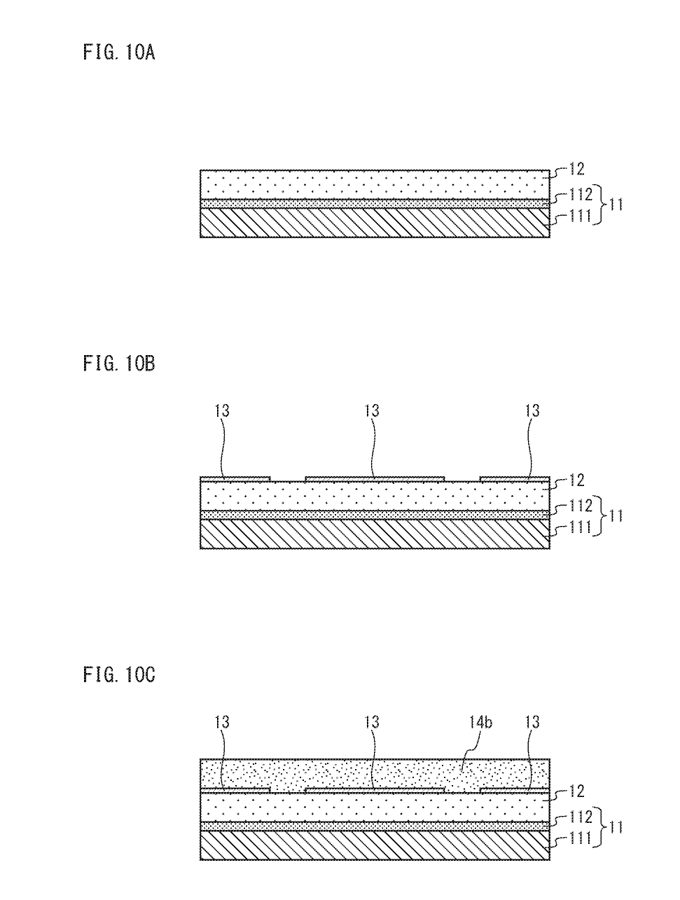

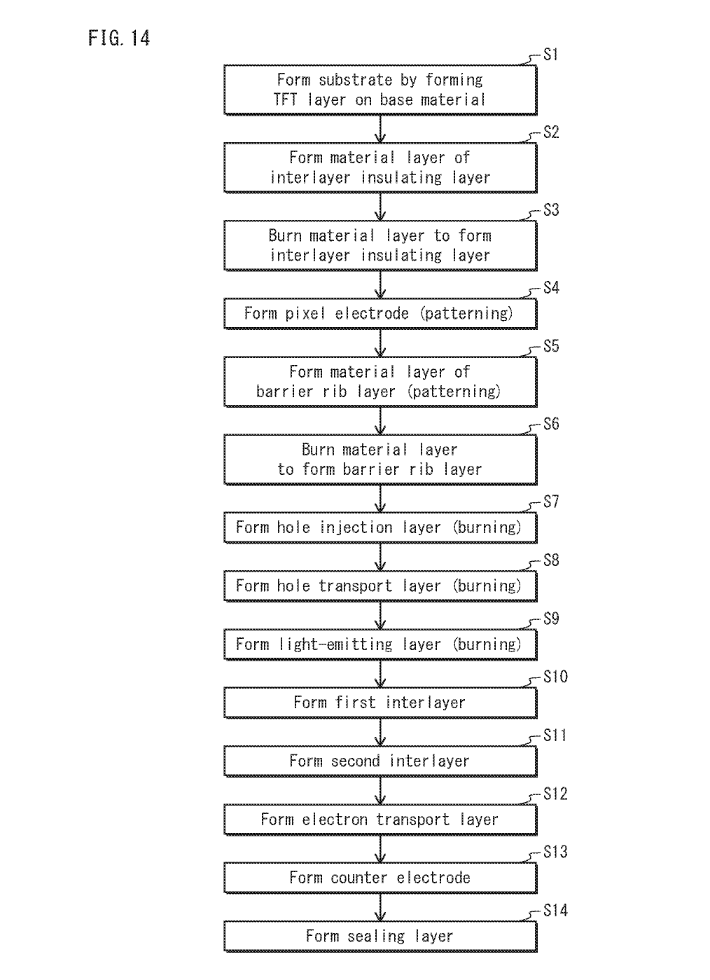

The following explains a manufacturing method of the organic EL element 1 with reference to FIGS. 10A-13C and 14. FIGS. 10A-13C are cross-sectional views schematically showing a manufacturing process of the organic EL element 1, and FIG. 14 is a flow chart schematically showing the manufacturing process of the organic EL element 1.

As shown in FIG. 10A, a substrate 11 is formed by forming a TFT layer 112 on a base material 111 (Step S1 in FIG. 14), and an interlayer insulating layer 12 is formed on the substrate 11 (Step S2 in FIG. 14). In the present embodiment, as a resin for an interlayer insulating layer that is a material of the interlayer insulating layer 12, acrylic resin, which is a positive photosensitive material, is used. The interlayer insulating layer 12 is formed by applying solution for the interlayer insulating layer onto the substrate 11, and burning the solution (Step S3 in FIG. 14). The solution for the interlayer insulating layer is solution in which acrylic resin, which is resin for interlayer insulating layer, is dissolved in solvent for the interlayer insulating layer such as PGMEA. Burning of the solution is performed at a temperature of 150 degrees C. to 210 degrees C. for 180 minutes.

Although not shown in the cross-sectional views in FIGS. 10A-13C and the flow chart in FIG. 14, while the interlayer insulating layer 12 is formed, a contact hole is formed by performing pattern exposure and developing. Since the interlayer insulating layer 12 becomes solid after burning, the contact hole is formed more easily before burning the interlayer insulating layer 12 than after burning the interlayer insulating layer 12.

Then, a pixel electrode 13 is formed for each subpixel as shown in FIG. 10B by forming a film having a thickness of approximate 150 nm from a metal material using a vacuum deposition method or a sputtering method (Step S4 in FIG. 14).

Next, a barrier rib material layer 14b is formed by applying a resin for a barrier rib layer that is a material of a barrier rib layer 14 onto the pixel electrode 13 (FIG. 10C). As the resin for the barrier rib layer, phenol resin, which is a positive photosensitive material, is for example used. The barrier rib material layer 14b is formed by uniformly applying, onto the pixel electrode 13, solution in which phenol resin, which is the resin for the barrier rib layer is dissolved in solvent (such as mixed solvent of ethyl lactate and GBL).

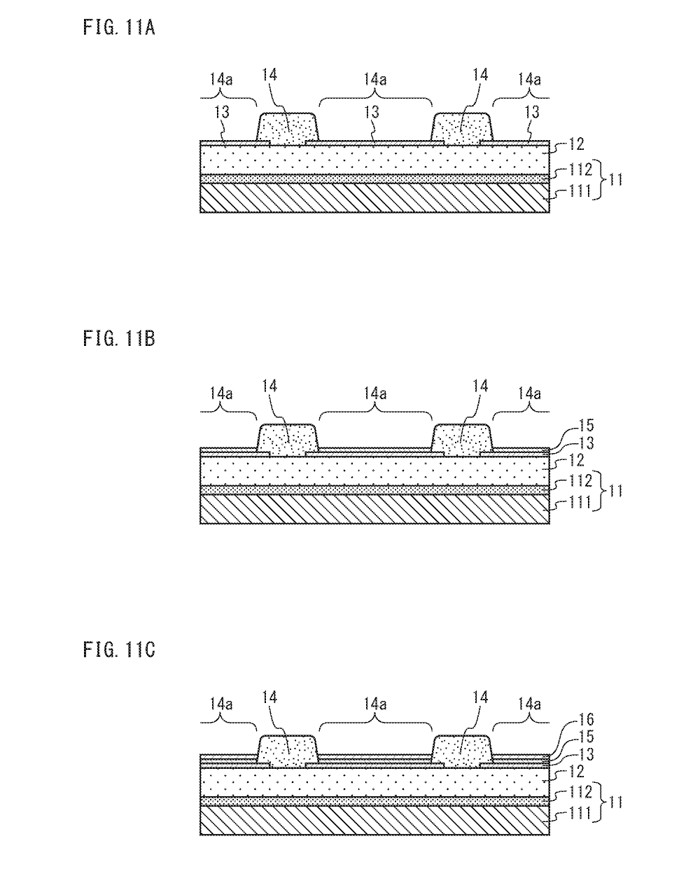

Next, the barrier rib layer 14 is formed by performing exposure and developing on the barrier rib material layer 14b to pattern the barrier rib material layer 14b to the shape of the barrier rib layer 14 (FIG. 11A and Step S5 in FIG. 14), and burning the barrier rib material layer 14b (Step S6 in FIG. 14). Burning of the barrier rib material layer 14b is performed for example at a temperature of 150 degrees C. to 210 degrees C. for 60 minutes. The barrier rib layer 14, which is formed, defines an opening 14a that is a region in which a light-emitting layer 17 is to be formed.

In a process of forming the barrier rib layer 14, a surface of the barrier rib layer 14 may undergo surface processing with use of predetermined alkaline solution, water, organic solvent, or the like, or plasma processing. Surface processing of the barrier rib layer 14 is performed in order to adjust a contact angle of the barrier rib layer 14 relative to ink to be applied to the opening 14a or to provide the surface of the barrier rib layer 14 with repellency.

Then, a hole injection layer 15 is formed as shown in FIG. 11B by forming a film from a material of the hole injection layer 15 using an applying method such as a mask vapor deposition method and an inkjet method, and burning the film (Step S7 in FIG. 14).

Next, a hole transport layer 16 is formed as shown in FIG. 11C by applying ink including a material of the hole transport layer 16 to the opening 14a defined by the barrier rib layer 14, and burning (and drying) the ink (Step S8 in FIG. 14).

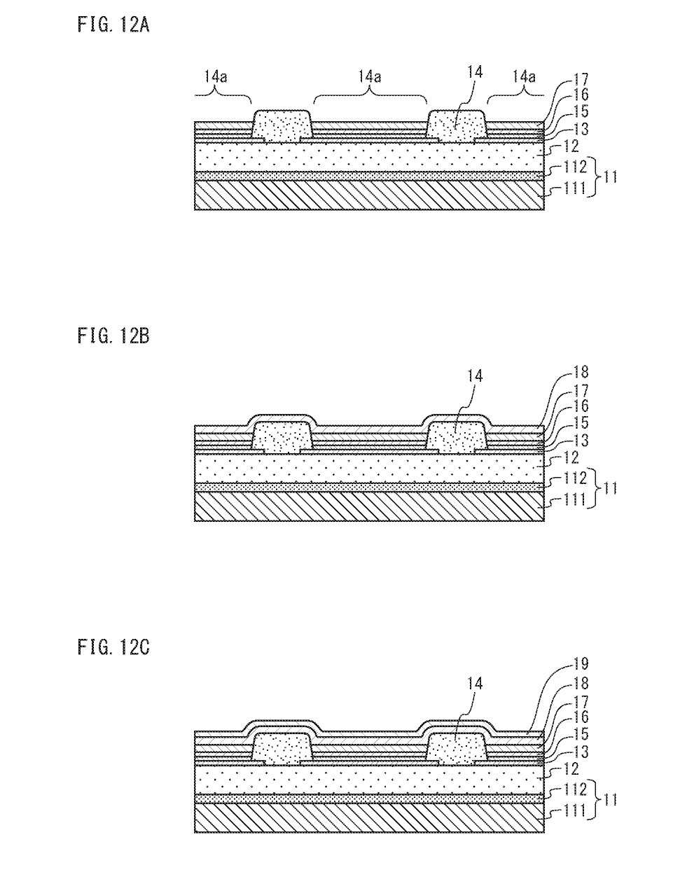

Similarly, the light-emitting layer 17 is formed as shown in FIG. 12A by applying ink including a material of the light-emitting layer 17, and burning (and drying) the ink (Step S9 in FIG. 14).

Then, as shown in FIG. 12B, a first interlayer 18 having a thickness D1 is formed on the light-emitting layer 17 using the vacuum deposition method or the like (Step S10 in FIG. 14). The first interlayer 18 is also formed on the barrier rib layer 14. Then, as shown in FIG. 12C, a second interlayer 19 having a thickness D2 is formed on the first interlayer 18 using the vacuum deposition method or the like (Step S11 in FIG. 14).

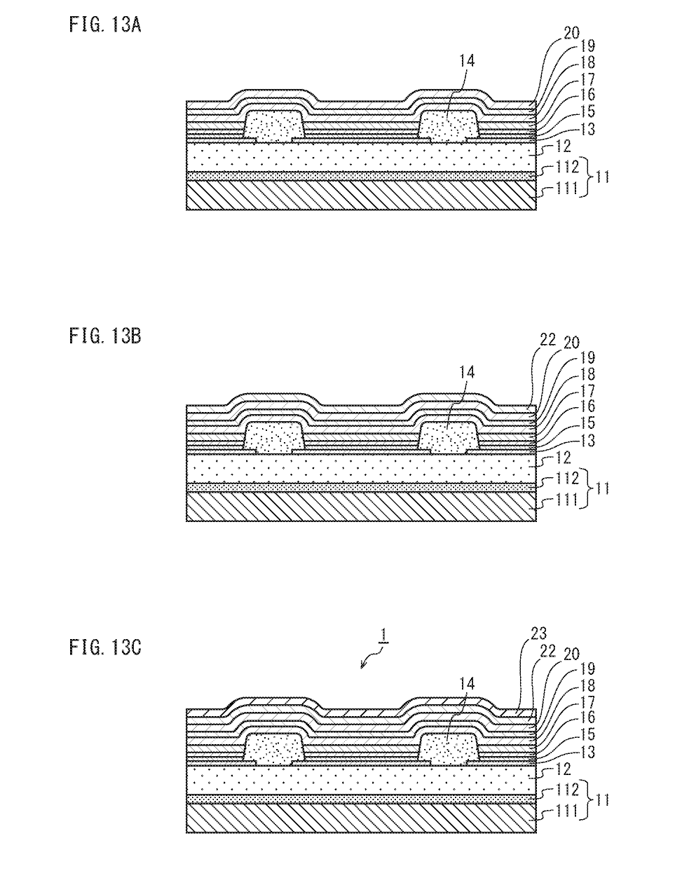

Next, an electron transport layer 20 is formed as shown in FIG. 13A by forming an organic material included in the electron transport layer 20 using the vacuum deposition method while doping the organic material with the second metal (Step S12 in FIG. 14).

Next, a counter electrode 22 is formed on the electron transport layer 20 as shown in FIG. 13B by forming a film from a metal material and so on using the vacuum deposition method, the sputtering method, or the like (Step S13 in FIG. 14).

Then, a sealing layer 23 is formed on the counter electrode 22 as shown in FIG. 13C by forming a film from a light-transmissive material such as SiN and SiON using the sputtering method, a CVD method, or the like (Step S14 in FIG. 14).

Through the above processes, an organic EL element 1 is complete, and an organic EL display panel 100 including a plurality of organic EL elements 1 is also complete. Note that a color filter, an upper substrate, and so on may be adhered onto the sealing layer 23.

[11. Overall Structure of Organic EL Display Device]

FIG. 15 is a block diagram schematically showing the overall structure of an organic EL display device 1000. As shown in the figure, the organic EL display device 1000 includes the organic EL display panel 100 and a drive control unit 200 that is connected to the organic EL display panel 100. The drive control unit 200 includes four drive circuits 210 to 240 and a control circuit 250.

In the actual organic EL display device 1000, the drive control unit 200 is not limited to this arrangement relative to the organic EL display panel 100.

### Summary of Embodiment 1

According to the organic EL element 1 relating to Embodiment 1, the first interlayer 18 prevents intrusion of impurities from the light-emitting layer 17 into the functional layer 21 and the counter electrode 22, and the second interlayer 19 promotes electron injection from the counter electrode 22 to the light-emitting layer 17. This exhibits excellent storage stability and luminous property.

Further, the ratio D2/D1, which is the ratio of the thickness D2 of the second interlayer 19 to the thickness D1 of the first interlayer 18, satisfies 3%≦D2/D1<25%. This exhibits an excellent luminous efficiency.

Since the thickness D2 of the second interlayer 19 is 1 nm or less, a low amount of light absorbed by the second interlayer 19 is achieved. This exhibits an excellent light extraction efficiency.

Further, the counter electrode 22 has a reduced sheet resistance by including therein the metal layer, which is made of the metal material such as Ag, compared with the case where the counter electrode 22 is made only of a metal oxide material such as ITO. Then, improvement of conductivity of the counter electrode 22 reduces decrease of voltage during supply of power to the organic EL element 1, which is disposed on the center part of the organic EL display panel 100.

Further, inclusion of the metal layer in the counter electrode 22 improves the resonance effect of the optical cavity formed in the organic EL element 1, compared with the case where the counter electrode 22 is made only of the metal oxide material. As a result, the light-extraction efficiency of the organic EL element 1 is improved.

Note that the conditions for the values and the ratio of the thickness in the above explanation do not necessarily need to be satisfied with respect to the whole region of each subpixel defined by the opening 14a, and only need to be satisfied with respect to the center part of the subpixel.

### Embodiment 2

An organic EL element relating to Embodiment 2 has the same structure as the organic EL element 1 explained in the above Embodiment 1 except the functional layer 21. Specifically, in the present embodiment, the functional layer 21 does not include the second interlayer 19, which is made of a simple substance of Ba, and includes an electron transport layer 20, which includes Ba and is directly formed on the first interlayer 18. The organic EL element relating to the present embodiment has this structure in consideration of the following point.

In the above Embodiment 1, the second interlayer 19, which is made of the second metal (Ba), is formed on the first interlayer 18, which is made of fluoride of the first metal (Na). In this case, it is necessary to form the second interlayer 19, which is made of the second metal (Ba), so as to have a small thickness of 2 nm or less in order to exhibit an excellent luminous property. This is because of the following reason. In the case where the second interlayer 19 has an excessively large thickness relative to the first interlayer 18, NaF in the first interlayer 18 is cleaved more than necessary, and as a result the electron injection property increases more than necessary. This disturbs the balance between a supply amount of holes and a supply amount of electrons in the light-emitting layer 17, and degrades the luminous efficiency.

On the other hand, in order to form the second interlayer 19 so as to be thin using the vapor deposition method, it is necessary to perform vapor deposition at a low rate. Accordingly, a long time is necessary for forming the second interlayer 19, and control on formation of the second interlayer 19 is difficult.

Further, it is difficult to form the second interlayer 19 so as to be thin and uniform. As a result, there exist a part where the second interlayer 19 is formed and a part where the second interlayer 19 is not formed on the first interlayer 18.

In the present embodiment, taking into consideration this point, the electron transport layer 20, which is doped with Ba, is formed directly on the first interlayer 18, instead of forming the second interlayer 19, which is made of a simple substance of Ba, on the first interlayer 18.

FIG. 7B shows a layer structure of a blue organic EL element relating to Embodiment 2.

According to the organic EL element relating to the present embodiment, similarly to the organic EL element 1 relating to Embodiment 1, fluoride of the first metal (NaF) prevents intrusion of impurities from the light-emitting layer 17 and reaction of Ba included in the functional layer 21 with impurities. This suppresses degradation of the electron supply property of the functional layer 21, and further prevents degradation of the counter electrode 22 due to impurities.

Further, according to the organic EL element relating to the present embodiment, the second interlayer 19, which is made of a simple substance of Ba, is not formed on the first interlayer 18. Instead, Ba with which the electron transport layer 20, which is adjacent to the first interlayer 18, is doped cleaves the bond between Na and F in NaF included in the first interlayer 18 to liberate Na. Then, the liberated Na assists movement of electrons from the electron transport layer 20 to the light-emitting layer 17, and thereby the electron injection property of the first interlayer 18 is ensured.

In the present embodiment, the electron transport layer 20 should preferably be doped with Ba at a concentration of 5 wt % to 40 wt % in order to exhibit an excellent luminous efficiency similarly to that in Embodiment 1, as explained in Embodiment 1 based on the graph shown in FIG. 6.

The organic EL element 1 relating to Embodiment 1 includes the second interlayer 19, which is made of the second metal (Ba), directly below the electron transport layer 20, and accordingly exhibits an excellent luminous efficiency irrespective of a low concentration of the doping metal (Ba) in the electron transport layer 20. Compared with this, the organic EL element relating to the present embodiment does not include the second interlayer 19. Accordingly, the electron transport layer 20 should preferably be doped with Ba at a comparatively high concentration within the range of 5 wt % to 40 wt %, specifically, at a concentration of 20 wt % to 40 wt %.

Also, the organic EL element relating to the present embodiment does not include the second interlayer 19, and has a less amount of Ba in the region adjacent to the first interlayer 18 than that of Embodiment 1. Accordingly, the organic EL element relating to the present embodiment has a lower property of cleaving the bond in NaF than that of Embodiment 1. Therefore, in the present embodiment, the first interlayer 18 should preferably have a smaller thickness than that of Embodiment 1, specifically a thickness of 2 nm or less.

The optical thickness of each of the layers included in the organic EL element relating to Embodiment 1 is applicable to the organic EL element relating to the present embodiment except that the organic EL element relating to the present embodiment does not include the second interlayer 19.

### Modifications

Although the explanation has been given on Embodiments 1 and 2, the present disclosure is not limited to these embodiments. The following modifications for example may be made.

### Modification 1

The organic EL element relating to each of the above embodiments includes the hole injection layer 15 and the hole transport layer 16. Alternatively, an organic EL element that does not include at least one of these layers may be similarly embodied.

### Modification 2

Further, the organic EL element relating to the present disclosure may include an electron injection layer, a transparent conductive layer, and so on. In the case where the organic EL element includes the electron injection layer, the electron injection layer and the electron transport layer may be collected as the functional layer. Also, in the case where the organic EL element does not include the electron transport layer and includes the electron injection layer, the electron injection layer may be dealt as the functional layer.

### Modification 3

In the above embodiments, the explanation has been given on the example in which glass is used as the insulating material of the base material 111 included in the organic EL element. However, the insulating material of the base material 111 is not limited to this. Alternatively, resin, ceramic, or the like may be used as the insulating material of the base material 111. Examples of the resin used for the base material 111 include polyimide resin, acrylic resin, styrene resin, polycarbonate resin, epoxy resin, polyethersulfone, polyethylene, polyester, and silicone resin. Examples of ceramic used for the base material 111 include aluminum.

### Modification 4

In the above embodiments, the organic EL display panel 100 is of the top-emission type according to which the pixel electrode 13 is a light-reflective anode and the counter electrode 22 is a light-transmissive cathode. Alternatively, the organic EL display panel may of the bottom-emission type according to which a pixel electrode is a light-transmissive cathode and a counter electrode is a light-reflective anode.

In this case, the organic EL display panel has the following structure for example. The pixel electrode 13 as a cathode and the barrier rib layer 14 are formed on the interlayer insulating layer 12. Within the opening 14a, the functional layer 21, the first interlayer 18, and the light-emitting layer 17 are formed on the pixel electrode 13 in respective order. The hole transport layer 16 and the hole injection layer 15 are formed on the light-emitting layer 17 in respective order. The counter electrode 22 as an anode is formed on the hole injection layer 15.

The organic EL element and the organic EL display panel relating to the present disclosure are utilizable for displays for use in various types of display devices for households, public facilities, and business, displays for television devices, portable electronic devices, and so on.

Although the technology pertaining to the present disclosure has been fully described by way of examples with reference to the accompanying drawings, it is to be noted that various changes and modifications will be apparent to those skilled in the art. Therefore, unless such changes and modifications depart from the scope of the present disclosure, they should be construed as being included therein.

1. An organic EL element comprising:
a light-reflective anode;
a light-emitting layer that is disposed above the anode;
a fluorine compound layer that is disposed on the light-emitting layer, and includes a fluorine compound including a first metal that is an alkali metal or an alkaline-earth metal;
a functional layer that is disposed on the fluorine compound layer, and has at least one of an electron transport property and an electron injection property;
a light-transmissive cathode that is disposed above the functional layer, and includes a metal layer, wherein
the functional layer includes a second metal in a region thereof that is in contact with the fluorine compound layer, the second metal being an alkali metal or an alkaline-earth metal.

2. The organic EL element of claim 1, wherein
the metal layer is made of silver, silver alloy, aluminum, or aluminum alloy.

3. The organic EL element of claim 1, wherein
the functional layer is made of an organic material, the organic metal having an electron transport property and being doped with the second metal.

4. The organic EL element of claim 3, wherein
the functional layer is doped with the second metal at a concentration of 5 wt % to 40 wt %.

5. The organic EL element of claim 1, wherein
the functional layer includes:
an organic layer that is made of an organic material having an electron transport property; and
an interlayer that is disposed between the organic layer and the fluorine compound layer, and is made of a simple substance of the second metal.

6. The organic EL element of claim 5, wherein
the organic layer is doped with the second metal.

7. The organic EL element of claim 1, wherein
the second metal is barium.

8. The organic EL element of claim 1, wherein
the first metal is sodium.

9. The organic EL element of claim 1, wherein
the light-emitting layer emits blue light,
an optical cavity is formed between the anode and the cathode, and
a total optical thickness of the light-emitting layer, the fluorine compound layer, and the functional layer is set so as to correspond to an index luminance/y that falls within a range of the index luminance/y at a primary interference and is equal to or higher than a local maximum of the index luminance/y at a secondary interference and according to characteristics of the index luminance/y that varies in accordance with variation of an optical thickness of the functional layer, where luminance and y are luminance and a value y in an x-y chromaticity of the blue light extracted from the organic EL element, respectively.

10. An organic EL element comprising:
a light-reflective anode;
a light-emitting layer that is disposed above the anode;
a fluorine compound layer that is disposed on the light-emitting layer, and includes a fluorine compound including a first metal that is an alkali metal or an alkaline-earth metal;
a functional layer that is disposed on the fluorine compound layer, and has at least one of an electron transport property and an electron injection property;
a light-transmissive cathode that is disposed above the functional layer, and includes a metal layer, wherein
the functional layer includes a second metal in a region thereof that is in contact with the fluorine compound layer, the second metal having a property of cleaving a bond between the first metal and fluorine in the fluorine compound.

11. A manufacturing method of an organic EL element comprising:
forming a light-reflective anode;
forming, above the anode, a light-emitting layer;
forming, on the light-emitting layer, a fluorine compound layer that includes a fluorine compound including a first metal that is an alkali metal or an alkaline-earth metal;
forming, on the fluorine compound layer, a functional layer that has at least one of an electron transport property and an electron injection property;
forming, above the functional layer, a light-transmissive cathode that includes a metal layer, wherein
the functional layer includes a second metal in a region thereof that is in contact with the fluorine compound layer, the second metal being an alkali metal or an alkaline-earth metal.

12. The manufacturing method of claim 11, wherein
the metal layer is made of silver, silver alloy, aluminum, or aluminum alloy.

13. The manufacturing method of claim 11, wherein
in forming the functional layer,
an organic material having an electron transport property is doped with the second metal.

14. The manufacturing method of claim 14, wherein
in forming the functional layer,
the organic material is doped with the second metal at a concentration of 5 wt % to 40 wt %.

15. The manufacturing method of claim 11, wherein
in forming the functional layer,
an interlayer is formed on the fluorine compound layer from a simple substance of the second metal, and
an organic layer is formed on the interlayer from an organic material having an electron transport property.

16. The manufacturing method of claim 11, wherein
the second metal is barium.

17. The manufacturing method of claim 11, wherein
the first metal is sodium.
